(19) United States
(12) Patent Application Publication
(10) Pub. No.: US 2026/0140553 A1
(43) Pub. Date: May 21, 2026

(54) HEAT DISSIPATION STRUCTURE AND ELECTRONIC DEVICE COMPRISING SAME

(71) Applicant: Samsung Electronics Co., Ltd., Suwon-si (KR)

(72) Inventors: Kyuhwan LEE, Suwon-si (KR); Haejin LEE, Suwon-si (KR)

(21) Appl. No.: 19/451,848

(22) Filed: Jan. 16, 2026

Related U.S. Application Data
(63) Continuation of application No. PCT/KR2024/010228, filed on Jul. 17, 2024.

(30) Foreign Application Priority Data
Jul. 18, 2023 (KR) 10-2023-0092934
Oct. 12, 2023 (KR) 10-2023-0136186

(51) Int. Cl. G06F 1/20; G06F 1/16; H05K 7/20

(52) U.S. Cl. CPC G06F 1/203; G06F 1/1652; G06F 1/1681; H05K 7/2039; G06F 2200/203

(57) ABSTRACT

An electronic device may include: a first housing; a second housing; a hinge rotatably coupling the first housing and the second housing; a flexible display changing in response to a relative motion of the second housing with respect to the first housing; and a heat dissipation structure disposed between the flexible display and the hinge, and including: a heat dissipation layer stacked on the flexible display including a first heat dissipation layer positioned in the first housing and a second heat dissipation layer positioned in the second housing; and a heat conduction layer stacked on at least a portion of the heat dissipation layer and thermally connecting the first heat dissipation layer and the second heat dissipation layer. Heat generated in the first housing may be transferred to the second housing through the first heat dissipation layer, the heat conductive layer, and the second heat dissipation layer.

### CROSS-REFERENCE TO RELATED APPLICATIONS

This application is a continuation of International Application No. PCT/KR2024/010228 designating the United States, filed on Jul. 17, 2024, in the Korean Intellectual Property Receiving Office and claiming priority to Korean Patent Application Nos. 10-2023-0092934, filed on Jul. 18, 2023, and 10-2023-0136186, filed on Oct. 12, 2023, in the Korean Intellectual Property Office, the disclosures of each of which are incorporated by reference herein in their entireties.

### BACKGROUND

### Field

The disclosure relates to a heat dissipation structure and an electronic device including the same.

### Description of Related Art

With the remarkable advancement of information and communication technology and semiconductor technology, the distribution and use of various electronic devices are rapidly increasing. Recent electronic devices are being developed to be portable and capable of communication.

An electronic device may refer to a device that performs a specific function according to a mounted program, such as home appliances, electronic organizers, portable multimedia players, mobile communication terminals, tablet PCs, video/audio devices, desktop/laptop computers, or vehicle navigation systems. For example, such electronic devices may output stored information as sound or video. As the integration density of electronic devices increases and ultra-high-speed, high-capacity wireless communication becomes common, recently, a function may be mounted on a single electronic device such as a mobile communication terminal. For example, not only a communication function but also an entertainment function such as a game, a multimedia function such as music/video playback, a communication and security function for mobile banking, and a function such as schedule management or electronic wallet are being integrated into a single electronic device. These electronic devices have been downsized to be conveniently carried by users. As the carrying and use of compact and slim mobile devices, e.g., smartphones, become commonplace, users demand diversified, high-class exterior design for mobile devices.

### SUMMARY

An electronic device according to an example embodiment of the disclosure, may comprise: a first housing, a second housing, a hinge configured to rotatably couple the first housing and the second housing, a flexible display configured to vary corresponding to a relative motion of the second housing with respect to the first housing, and a heat dissipation structure comprising at least one layer of heat dissipating material at least partially disposed between the flexible display and the hinge.

The heat dissipation structure may include a heat dissipation layer stacked with the flexible display, wherein the heat dissipation layer includes a first heat dissipation layer located in the first housing, and a second heat dissipation layer located in the second housing, and a heat conductive layer stacked with at least a portion of the heat dissipation layer and configured to thermally couple the first heat dissipation layer and the second heat dissipation layer.

Heat generated in the first housing may be configured to be transferred to the second housing through the first heat dissipation layer, the heat conductive layer, and the second heat dissipation layer.

An electronic device according to an example embodiment of the disclosure, may comprise: a first housing, a second housing, a hinge configured to rotatably couple the first housing and the second housing, a flexible display configured to vary corresponding to a relative motion of the second housing with respect to the first housing, and a heat dissipation structure comprising a heat dissipating material at least partially disposed between the flexible display and the hinge.

The heat dissipation structure may include a heat dissipation layer stacked with the flexible display, the heat dissipation layer including a first heat dissipation layer located in the first housing, a second heat dissipation layer located in the second housing, a heat conductive layer stacked with at least a portion of the heat dissipation layer and configured to thermally couple the first heat dissipation layer and the second heat dissipation layer, and an anti-stick layer disposed between the heat conductive layer and the heat dissipation layer.

Heat generated in the first housing may be configured to be transferred sequentially to the second housing through the first heat dissipation layer, the heat conductive layer, and the second heat dissipation layer.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments.

FIG. 2 is a diagram illustrating a front view, side view, and rear view of an example electronic device in an unfolded state according to various embodiments.

FIG. 3 is a diagram illustrating a front view, side view, and rear view of an example electronic device in a folded state according to various embodiments.

FIG. 4 is an exploded perspective view illustrating an example electronic device according to various embodiments.

FIG. 5 is a diagram illustrating a flexible display and a heat dissipation structure, and illustrating a heat transfer path according to various embodiments.

FIGS. 6 and 7 are cross-sectional views illustrating a portion of the display and the heat dissipation structure of FIG. 5 taken along line B-B′ according to various embodiments.

FIGS. 8A and 8B are cross-sectional views illustrating a portion of the heat dissipation structure including the anti-stick layer of FIG. 5 taken along line B-B′ according to various embodiments.

FIGS. 9A and 9B are cross-sectional views illustrating a portion of the heat dissipation structure including the surface protective layer of FIG. 5 taken along line B-B′ according to various embodiments.

FIG. 10 is a cross-sectional view illustrating a portion of the heat dissipation structure of FIG. 5 taken along line B-B′ when the electronic device is in an unfolded state according to various embodiments.

FIG. 11 is a cross-sectional view illustrating a portion of the heat dissipation structure of FIG. 5 taken along line B-B′ when the electronic device is in a folded state according to various embodiments.

FIG. 12 is a cross-sectional view illustrating a portion of the heat dissipation structure including an adhesive layer taken along line B-B′ according to various embodiments.

FIG. 13 is a cross-sectional view illustrating a portion of the heat dissipation structure including a heat dissipation layer taken along line B-B′ according to various embodiments.

FIG. 14 is a cross-sectional view illustrating a portion of the heat dissipation structure including a heat dissipation layer with a step taken along line B-B′ according to various embodiments.

FIG. 15 is a cross-sectional view illustrating a portion of the heat dissipation structure including a heat dissipation layer taken along line B-B′ according to various embodiments.

FIGS. 16 and 17 are cross-sectional views illustrating a portion of the heat dissipation structure further including a protective film taken along line B-B′ according to various embodiments.

FIG. 18 is a cross-sectional view illustrating a portion of the heat dissipation structure further including a second anti-stick layer taken along line B-B′ according to various embodiments.

FIG. 19 is a cross-sectional view illustrating a portion of a separable heat dissipation structure taken along line B-B′ according to various embodiments.

### DETAILED DESCRIPTION

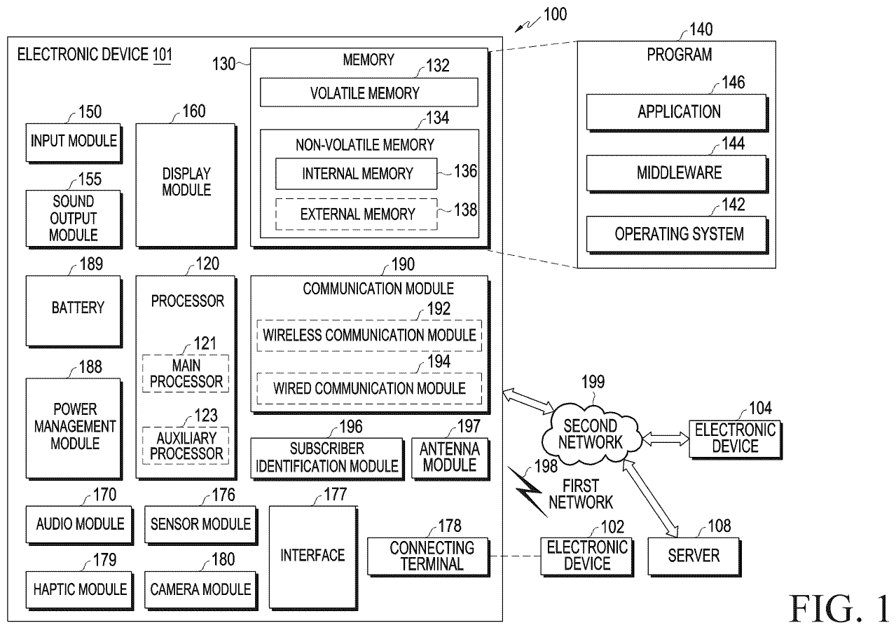

FIG. 1 is a block diagram illustrating an example electronic device 101 in a network environment 100 according to various embodiments.

Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store a piece of data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operation state (e.g., power or temperature) of the electronic device 101 or an external environmental state (e.g., the user's state), and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wiredly) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and support a direct (e.g., wiredly) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support a requirement specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module may include an antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to an embodiment of the disclosure may be one type of electronic device. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

The disclosure and terms used therein are not intended to limit the technical features described in the disclosure to specific embodiments, and should be understood to include a modification, equivalent, or substitute of the embodiment. In connection to the description of the drawings, similar reference numerals may be used for similar or related components. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used herein, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

An embodiment as set forth herein may be implemented as software (e.g., the program) including one or more instructions that are stored in a storage medium (e.g., internal memory or external memory) that is readable by a machine (e.g., the electronic device). For example, a processor (e.g., the processor) of the machine (e.g., the electronic device) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Here, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

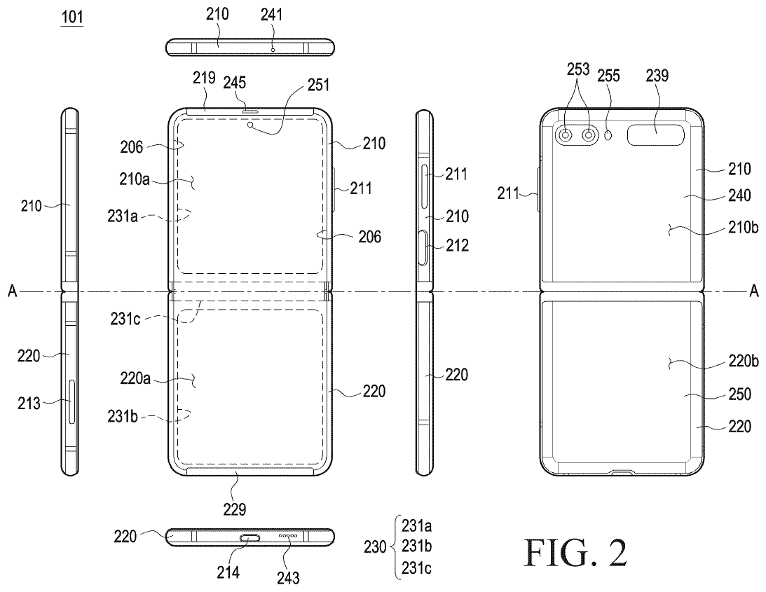

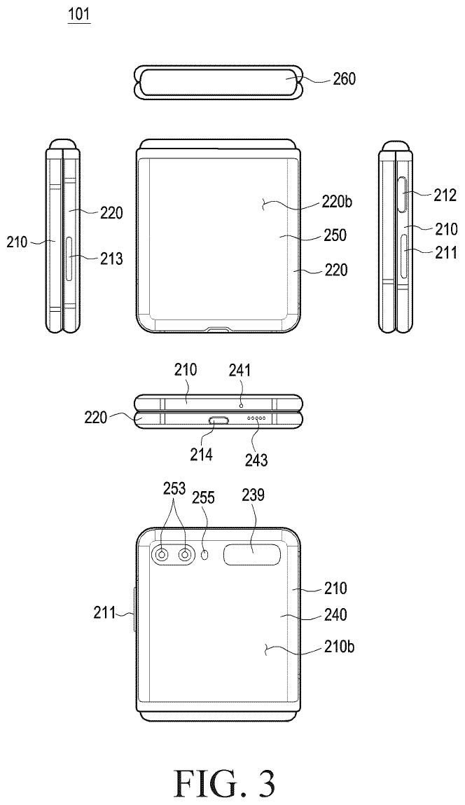

FIG. 2 is a diagram illustrating a front view, side view, and rear view of an example electronic device 101 in an unfolded state according to various embodiments. FIG. 3 is a diagram illustrating a front view, side view, and rear view of an example electronic device 101 in a folded state according to various embodiments.

Referring to FIGS. 2 and 3, according to an embodiment, an electronic device 101 may include a first housing 210, a second housing 220, a flexible or foldable display 230 (hereinafter, simply “display 230”) (e.g., the display module 160 of FIG. 1) disposed in the space provided by the first housing 210 and the second housing 220, and a hinge cover 260.

According to an embodiment, the surface on which the display 230 is disposed may be defined as a front surface of the electronic device 101. At least a portion of the front surface of the electronic device 101 may be formed of a substantially transparent front plate (e.g., a glass plate or polymer plate including coat layers). The opposite surface of the front surface may be defined as a rear surface of the electronic device 101. The rear surface of the electronic device 101 may be formed by a substantially opaque rear plate (hereinafter, referred to as a ‘rear cover’). The rear cover may be formed of, e.g., laminated or colored glass, ceramic, polymer, metal (e.g., aluminum, stainless steel (STS), or magnesium), or a combination of at least two thereof. The surface surrounding the space between the front and back surfaces may be defined as a side surface of the electronic device 101. The side surface may be formed by a side bezel structure (or a “side member”) that couples to the front plate and the rear plate and includes a metal and/or polymer. According to an embodiment, the rear cover and the side bezel structure may be integrally formed together and include the same material (e.g., a metal, such as aluminum).

The electronic device 101 may include at least one or more of a display 230, audio modules 241, 243, 245, a sensor module 255, a camera module 253, key input devices 211, 212, 213, and a connector hole 214. According to an embodiment, the electronic device 101 may omit at least one (e.g., the key input devices 211, 212, 213) of the components or additionally include another component (e.g., a light emitting device).

According to an embodiment, the display 230 may be a display at least a portion of which may be transformed into a flat or curved surface. According to an embodiment, the display 230 may include a folding area 231c, a first area 231a disposed on one side of the folding area 231c (e.g., an upper side of the folding area 231c of FIG. 2), and a second area 231b disposed on the opposite side of the folding area 231c (e.g., a lower side of the folding area 231c of FIG. 2). However, the segmentation of the display 230 as shown in FIG. 2 is merely an example, and the display 230 may be divided into a plurality of (e.g., four or more, or two) areas depending on the structure or function of the display 230. For example, in FIG. 2, the display 230 may be divided into the areas by the folding area 231c or folding axis A but, in an embodiment, the display 230 may be divided into the areas with respect to another folding area 231c or another folding axis (e.g., a folding axis perpendicular to the folding axis A).

According to an embodiment, the audio modules 241, 243, 245 may include a microphone hole 241 and speaker holes 243, 245. The microphone hole 241 may have a microphone inside to obtain external sounds. According to an embodiment, there may be a plurality of microphones to be able to detect the direction of a sound. The speaker holes 243, 245 may include an external speaker hole 243 and a phone receiver hole 245. According to an embodiment, the speaker holes 243, 245 and the microphone hole 241 may be implemented as a single hole, or speakers may rest without the speaker holes 243, 245 (e.g., piezo speakers). Various changes may be made to the position and number of microphone holes 241 and speaker holes 243, 245 according to an embodiment.

According to an embodiment, the electronic device 101 may include a first camera device 251 disposed on the first surface 210a of the first housing 210 and a second camera device 253 disposed on the second surface 210b. The electronic device 101 may further include a flash (not shown). The camera devices 251, 253 may include one or more lenses, an image sensor, and/or an image signal processor. The flash (not shown) may include, e.g., a light emitting diode or a xenon lamp.

According to an embodiment, the sensor module 255 may generate an electrical signal or a data value corresponding to an internal operating state of the electronic device 101 or an external environmental state. Although not shown in the drawings, the electronic device 101 may additionally or alternatively include a sensor module (e.g., the sensor module 176 of FIG. 1) other than the sensor module 255 provided on the second surface 210b of the first housing 210. The electronic device 101 may include, as the sensor module, at least one of a proximity sensor, a fingerprint sensor, an HRM sensor, a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor.

According to an embodiment, the key input devices 211, 212, 213 may be disposed on a side surface of the foldable housing (e.g., the first housing 210 or the second housing 220). According to an embodiment, the electronic device 101 may exclude all or some of the above-mentioned key input devices 211, 212, 213 and the excluded key input devices may be implemented in other forms, e.g., as soft keys, on the display 230. In an embodiment, the key input device may be configured to implement key input by a sensor module (e.g., a gesture sensor).

According to an embodiment, the connector hole 214 may be configured to receive a connector (e.g., a USB connector) for transmitting/receiving power and/or data to/from an external electronic device or, additionally or alternatively, a connector for transmitting/receiving audio signals to/from an external electronic device.

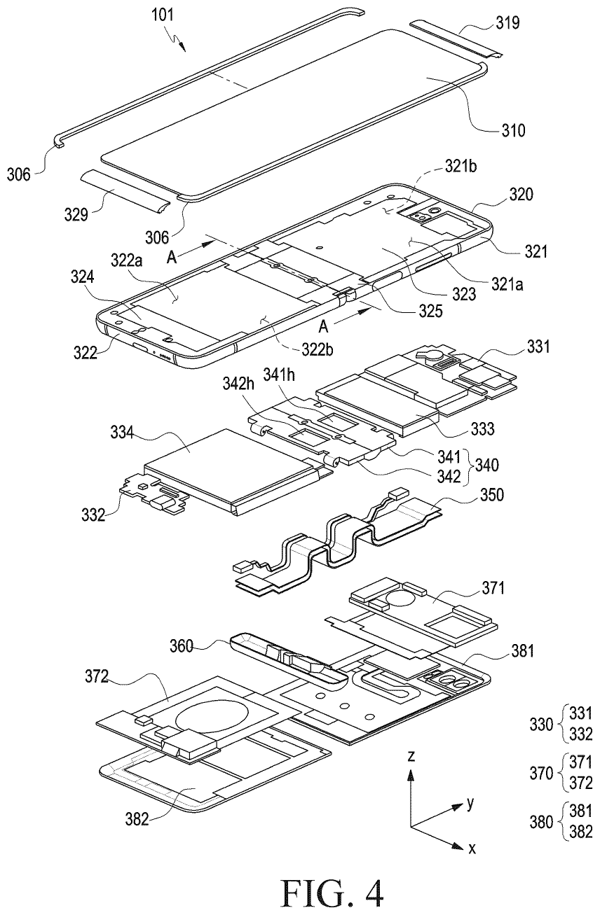

According to an embodiment, a foldable housing may be implemented by a combination of the first housing 210, the second housing 220, the first rear cover 240, the second rear cover 250, and the hinge module (e.g., the hinge structure 340 of FIG. 4). The foldable housing of the electronic device 101 are not limited to the shape and coupling shown but may rather be implemented in other shapes or via a combination and/or coupling of other components. For example, in an embodiment, the first housing 210 and the first rear cover 240 may be integrally formed with each other, and the second housing 220 and the second rear cover 250 may be integrally formed with each other. According to an embodiment of the disclosure, ‘housing’ may refer, for example, to a combination of another component not mentioned and/or a combined configuration thereof. For example, it may be described that a first area 231a of the display 230 forms one surface of the first housing 210 and, in an embodiment, the first area 231a of the display 230 is disposed or attached to one surface of the first housing 210.

According to an embodiment, the first housing 210 may be connected to the hinge structure (e.g., the hinge structure 340 of FIG. 4 described below) and may include a first surface 210a facing in a first direction and a second surface 210b facing in a second direction opposite to the first direction. The second housing 220 may be connected to the hinge structure (e.g., the hinge structure 340 of FIG. 4 described below) and may include a third surface 220a facing in a third direction and a fourth surface 220b facing in a fourth direction opposite to the third direction and may be rotated or pivoted from the first housing 210 about the hinge structure (or folding axis A).

According to an embodiment, the first housing 210 and the second housing 220 may be disposed on two opposite sides (or upper/lower sides) of the folding axis A and may overall have a symmetrical shape with respect to the folding axis A. The angle or distance between the first housing 210 and the second housing 220 may be varied depending on whether the electronic device 101 is in the unfolded state, the folded state, or the partially unfolded (or partially folded) intermediate state. According to an embodiment, the first housing 210 may further include sensors unlike the second housing 220 but, in the remaining area, the first housing 210 and the second housing 220 may have symmetrical shapes with each other.

According to an embodiment, the first housing 210 and the second housing 220 may at least partially be formed of a metal or non-metallic material with a rigidity selected to support the display 230. The at least a portion formed of the metal material may be provided as a ground plane or radiating conductor of the electronic device 101 and, if provided as the ground plane, it may be electrically connected with a ground line formed on the printed circuit board (e.g., the printed circuit board 330 of FIG. 4).

According to an embodiment, the first rear cover 240 may be disposed on one side (e.g., the upper side in FIG. 2) of the folding axis A, on the rear surface of the electronic device 101, e.g., it may have a substantially rectangular periphery which may be surrounded by the first housing 210 (and/or the side bezel structure). For example, the second rear cover 250 may be disposed on the opposite side (e.g., the lower side in FIG. 2) of the folding axis A on the rear surface of the electronic device 101 and its periphery may be surrounded by the second housing 220 (and/or the side bezel structure).

According to an embodiment, the first rear cover 240 and the second rear cover 250 may be substantially symmetrical in shape with respect to the folding axis A. However, the first rear cover 240 and the second rear cover 250 are not necessarily symmetrical in shape. In an embodiment, the electronic device 101 may include the first rear cover 240 and the second rear cover 250 in a shape. In an embodiment, the first rear cover 240 may be integrally formed with the first housing 210, and the second rear cover 250 may be integrally formed with the second housing 220.

According to an embodiment, the first rear cover 240, the second rear cover 250, the first housing 210, and the second housing 220 may form a space where a component (e.g., the printed circuit board 330 or battery 333, 334 of FIG. 4) of the electronic device 101 may be disposed. According to an embodiment, one or more components may be arranged or visually exposed on/through the rear surface of the electronic device 101. For example, at least a portion of a sub display 239 may be visible through the first rear cover 240. In an embodiment, one or more components or sensors may be visually exposed through the first rear cover 240. According to an embodiment, the components or sensors may include a proximity sensor, a rear camera, and/or a flash. Although not separately shown in the drawings, one or more other components or sensors may be visually exposed through the second rear cover 250.

According to an embodiment, the front camera 251 exposed from the front surface of the electronic device 101 through one or more openings or the rear camera 253 exposed through the first rear cover 240 may include one or more lenses, an image sensor, and/or an image signal processor. The flash (not shown) may include, e.g., a light emitting diode or a xenon lamp. In an embodiment, two or more lenses (infrared camera, wide-angle and telephoto lens) and image sensors may be disposed on one surface of the electronic device 101.

According to an embodiment, the electronic device 101 may transform into a folded state of the display or an unfolded state of the display. For example, the first housing 210 and the second housing 220 may be pivoted about each other between the folded state in which the housings 210, 220 face each other and a state (e.g., the state shown in FIG. 2, an unfolded state of the terminal) in which the housings 210, 220 are unfolded at a designated angle from the folded state.

According to an embodiment, the electronic device 101 may be implemented as two types, ‘in-folding’ in which the first area 231a and the second area 231b are folded to face each other, and ‘out-folding’ in which the first area 231a and the second area 231b are folded in face in opposite directions. For example, in the in-folding folded state, the first area 231a and the second area 231b may be substantially hidden and, in the fully unfolded state, the first area 231a and the second area 231b may be disposed to face substantially in the same direction. As another example, in the out-folding folded state, the first area 231a and the second area 231b are disposed to face in opposite directions, visible to the outside and, in the fully unfolded state, the first area 231a and the second area 231b may be disposed to face substantially in the same direction.

According to an embodiment, the display 230 may include a display panel (not shown) and a window member (not shown) and may be formed of a flexible material. Although not separately shown, it will be appreciated by one of ordinary skill in the art that the display 230 or display panel includes a layer(s), such as a light emitting layer, a substrate(s) for encapsulating the light emitting layer, an electrode or wiring layer, and/or adhesive layer(s) for bonding different layers. When the display 230 (e.g., the folding area 231c) is deformed into a flat or curved shape, a relative displacement may occur between the layers of the display 230. The relative displacement due to the deformation of the display 230 may increase as it is farther away from the folding axis A and/or as the thickness of the display 230 increases.

According to an embodiment, the window member, e.g., the thin film plate, may serve as a protective film to protect the display panel. As a protective film, the thin film plate may be formed of a material that protects the display panel from external impact, is resistant to scratches, and causes less creases in the folding area 231c even in repetitive folding and unfolding operations of the housings 210, 220. For example, the material of the thin film plate may include a clear polyimide (CPI) film or ultra-thin glass (UTG).

Referring to FIG. 3, the hinge cover 260 may be disposed between the first housing 210 and the second housing 220 to hide the internal components. According to an embodiment, the hinge cover 260 may be hidden by a portion of the first housing 210 and second housing 220 or be exposed to the outside depending on the state (e.g., the unfolded state (flat state), intermediate state, or folded state) of the electronic device 101.

According to an embodiment, as shown in FIG. 2, in the unfolded state of the electronic device 101, the hinge cover 260 may be hidden, and thus substantially not exposed, by the first housing 210 and the second housing 220. As another example, as shown in FIG. 3, in the folded state (e.g., a fully folded state) of the electronic device 101, the hinge cover 260 may be exposed to the outside between the first housing 210 and the second housing 220. As another example, in an intermediate state in which the first housing 210 and the second housing 220 are folded with a certain angle, the hinge cover 260 may be partially exposed to the outside between the first housing 210 and the second housing 220. However, in this case, the exposed area may be smaller than that in the completely folded state. In an embodiment, the hinge cover 260 may include a curved surface.

According to an embodiment, the electronic device 101 may further include a protection member(s) 206 or ornamental covers 219, 229 disposed at at least a portion of the edge of the display 230 on the front surface (e.g., the front surface 210a or the third surface 220a). The protection member 206 or ornamental covers 219, 229 may prevent and/or reduce at least a portion of the edge of the display 230 from contacting a mechanical structure (e.g., the first housing 210 or the second housing 220) and provide a decorative effect to the exterior of the electronic device 101.

FIG. 4 is an exploded perspective view illustrating an example electronic device 101 (e.g., the electronic device 101 of FIG. 2) according to various embodiments.

Referring to FIG. 4, in an embodiment, the electronic device 101 may include a display 310 (e.g., the display 230 of FIG. 2), a foldable housing (e.g., the first housing 321 and the second housing 322, the first housing 210 and second housing 220 of FIG. 2), a printed circuit board 330, a hinge structure 340, a flexible connection member 350, a hinge cover 360 (e.g., the hinge cover 260 of FIG. 3), an antenna module 370, and a rear cover 380. In an embodiment, the electronic device 101 may include at least one protection member 306 and/or at least one ornamental cover 319 or 329. The protection member 306 and/or the ornamental covers 319, 329 may be disposed adjacent to at least a portion of the circumference of the display 310 (e.g., the display 230 of FIG. 2).

According to an embodiment, the display 310 may be visible through a majority of the front surface of the electronic device 101. According to an embodiment, the shape of the display 310 may be formed to be substantially the same as the shape of the periphery of the front surface of the electronic device 101.

In FIG. 4, ‘y’ may refer, for example, to a length direction of the electronic device 101 in the second state. In an embodiment, ‘+y’ may refer, for example, to the upward direction of the electronic device 101 around the folding axis A of the electronic device 101, and ‘−y’ may refer, for example, to the downward direction of the electronic device 101 around the folding axis A of the electronic device 101.

According to an embodiment, the foldable housing of the electronic device 101 may include the first housing 321 and the second housing 322. According to an embodiment, the first housing 321 may include a first surface 321a and a second surface 321b facing in a direction opposite to the first surface 321a. The second housing 322 may include a third surface 322a and a fourth surface 322b facing in a direction opposite to the third surface 322a. The electronic device 101 or the foldable housing 321, 322 may additionally or alternatively include a bracket assembly 325. The bracket assembly 325 may include a first bracket assembly 323 disposed in the first housing 321 and a second bracket assembly 324 disposed in the second housing 322. At least a portion of the bracket assembly 325, e.g., at least a portion of the first bracket assembly 323 and at least a portion of the second bracket assembly 324, may serve as a plate for supporting the hinge structure 340.

According to an embodiment, an electric component may be disposed on the printed circuit board 330. For example, a processor (e.g., the processor 120 of FIG. 1), memory (e.g., the memory 130 of FIG. 1), and/or an interface (e.g., the interface 177 of FIG. 1) may be mounted on the printed circuit board 330. The processor may include one or more of, e.g., a central processing unit, an application processor, a graphic processing device, an image signal processor, a sensor hub processor, or a communication processor. The memory may include, e.g., a volatile or non-volatile memory. The interface may include, e.g., a high definition multimedia interface (HDMI), a universal serial bus (USB) interface, a secure digital (SD) card interface, and/or an audio interface. The interface may, e.g., electrically or physically connect the electronic device 101 to an external electronic device, and may include a USB connector, an SD card/MMC connector, or an audio connector.

According to an embodiment, the printed circuit board 330 may include a first printed circuit board 331 disposed on the side of the first bracket assembly 323 and a second printed circuit board 332 disposed on the side of the second bracket assembly 324. The first printed circuit board 331 and the second printed circuit board 332 may be disposed inside the space formed by the foldable housing 321, 322, the bracket assembly 325, the first rear cover 381 and/or the second rear cover 382. Components for implementing a function of the electronic device 101 may be disposed on the first printed circuit board 331 and the second printed circuit board 332. For example, a processor may be disposed on the first printed circuit board 331, and an audio interface may be disposed on the second printed circuit board 332.

According to an embodiment, batteries 333, 334 may be disposed adjacent to the printed circuit board 330 to supply power to the electronic device 101. At least a portion of the batteries 333, 334 may be disposed on substantially the same plane as the printed circuit board 330. According to an embodiment, a first battery 333 may be disposed adjacent to the first printed circuit board 331, and a second battery 334 may be disposed adjacent to the second printed circuit board 332. The batteries 333, 334 may be a device for supplying power to at least one component of the electronic device 101. The battery 189 may include, e.g., a primary cell which is not rechargeable, a secondary cell which is rechargeable, or a fuel cell. The batteries 333, 334 may be integrally or detachably disposed inside the foldable housing 321, 322.

According to an embodiment, the hinge structure 340 may be a component to provide a folding axis (e.g., the folding axis A of FIG. 2) and rotatably connect or couple the foldable housing 321, 322 and/or the bracket assembly 325. The hinge structure 340 may include a first hinge structure 341 disposed on the side of the first housing 321 and a second hinge structure 342 disposed on the side of the second housing 322. The hinge structure 340 may be disposed between the first housing 321 and the second housing 322. According to an embodiment, the hinge structure 340 may be formed substantially integrally with at least a portion of the first bracket assembly 323 and at least a portion of the second bracket assembly 324.

According to an embodiment, a ‘housing structure’ may include the foldable housing 321, 322 and may denote one resultant from assembling and/or combining at least one component disposed in the foldable housing 321, 322. The housing structure may include a first housing structure and a second housing structure. For example, a component assembled to include at least one component among the first housing 321 and the first bracket assembly 323, the first printed circuit board 331, and the first battery 333 disposed inside the first housing 321 may be referred to as the ‘first housing structure.’ As another example, a component assembled to include at least one component among the second housing 322 and the second bracket assembly 324, the second printed circuit board 332, and the second battery 334 disposed inside the second housing 322 may be referred to as the ‘second housing structure.’ However, it should be noted that the ‘first housing structure and the second housing structure’ are not limited to the addition of the above-described components, but may add or omit a component.

According to an embodiment, the flexible connection member 350 may include a flexible printed circuit board (FPCB). The flexible connecting member 350 may connect electrical elements disposed on the first printed circuit board 331 and the second printed circuit board 332. To this end, the flexible connecting member 350 may be disposed to cross the ‘first housing structure’ and the ‘second housing structure’. According to an embodiment, the flexible connecting member 350 may be disposed to cross at least a portion of the hinge structure 340. According to an embodiment, the flexible connection member 350 may be configured to connect the first printed circuit board 331 and the second printed circuit board 332 across the hinge structure 340 along a direction parallel to, e.g., the y axis of FIG. 4. As another example, the flexible connection member 350 may extend or be disposed through the openings 341h, 342h formed in the hinge structure 340. In this case, a portion of the flexible connection member 350 may be disposed over one side (e.g., upper portion) of the first hinge structure 341, and another portion of the flexible connection member 350 may be disposed over one side (e.g., upper portion) of the second hinge structure 342. Another portion of the flexible connection member 350 may be disposed on the other side (e.g., lower portion) of the first hinge structure 341 and the second hinge structure 342. A space (hereinafter, referred to as a ‘wiring space’) surrounded by at least a portion of the first hinge structure 341, at least a portion of the second hinge structure 342, and at least a portion of the hinge cover 360 may be formed in a position adjacent to the first hinge structure 341 and the second hinge structure 342. According to an embodiment, at least a portion of the flexible connection member 350 may be disposed in the wiring space.

According to an embodiment, the hinge cover 360 may be a component that covers at least a portion of the hinge structure 340 or the wiring space. In an embodiment, the hinge cover 360, together with the hinge structure 340, may form the wiring space and protect components (e.g., at least a portion 350c of the flexible connection member 350) disposed in the wiring space from external impact. According to an embodiment, the hinge cover 360 may be disposed between the first housing 321 and the second housing 322. In the electronic device 101 which is of an in-folding type, the hinge cover 360 may be at least partially concealed by the foldable housing 321, 322. For example, in the folded state, the hinge cover 360 may be visually exposed to the external space between the rear surface (e.g., the first rear cover 381) of the first housing 321 and the rear cover (e.g., the second rear cover 382) of the second housing 322 and, in the unfolded state, the hinge cover 360 may be substantially received inside the first housing 321 or the second housing 322 to be visually concealed.

According to an embodiment, the antenna module 370 (e.g., the antenna module 197 of FIG. 1) may be disposed between the rear cover 380 and the bracket assembly 323, 324. According to an embodiment, the antenna module 370 may include a first antenna module 371 disposed on the side of the first housing 321 and a second antenna module 372 disposed on the side of the second housing 322. The antenna module 370 may include, e.g., a near field communication (NFC) antenna, a wireless charging antenna, and/or a magnetic secure transmission (MST) antenna, performing short-range communication with an external device or wirelessly transmitting/receiving power required for charging. According to an embodiment, an antenna structure may be formed by a portion or combination of the side bezel structure of the foldable housing 321, 322 and/or bracket assembly.

According to an embodiment, the rear cover 380 may include a first rear cover 381 and a second rear cover 382. The rear cover 380 may be combined with the foldable housing 321, 322 to protect the above-described components (e.g., the printed circuit board 330, the batteries 333, 334, the flexible connection member 350, or the antenna module 370) disposed in the foldable housing 321, 322. As described above, the rear cover 380 may be formed substantially integrally with the foldable housing 321, 322.

According to an embodiment, the protection member 306 and/or the ornamental covers 319, 329 (e.g., the protection member 206 and/or the ornamental covers 219, 229 of FIG. 2) may protect at least a portion of the edge of the display 310. In an embodiment, the protection member 306 may be disposed between the edge of the display 310 and the inner wall of the first housing 321 and/or between the edge of the display 310 and the inner wall of the second housing 322 to prevent/reduce direct contact between the edge of the display 310 and the inner wall of the foldable housing 321, 322. In an embodiment, the ornamental cover 319 may be disposed on at least one of the first housing 310 and the second housing 320 and may be disposed to cover a portion of the edge of the display 310.

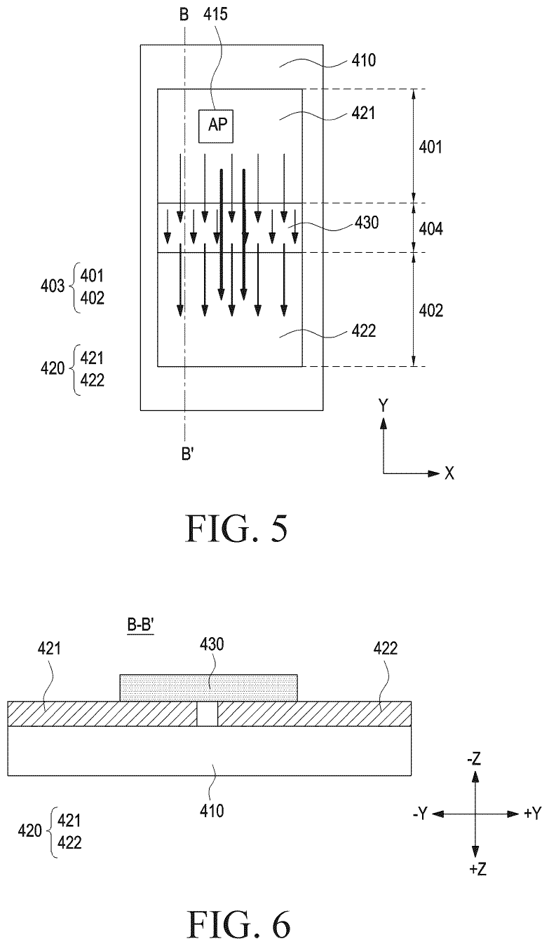

According to an embodiment, an electronic device may include a first housing 321, a second housing 322, and a hinge structure 340 rotatably coupling the first housing 321 and the second housing 322. The first housing 321 may include a first printed circuit board 331. The second housing 322 may include a second printed circuit board 332. The first printed circuit board 331 and the second printed circuit board 332 may be electrically connected through a flexible connecting member 350. For example, the first printed circuit board 331 may be a main printed circuit board, and the second printed circuit board 332 may be a sub printed circuit board. For example, a plurality of heat sources (e.g., the AP 415 of FIG. 5) generating heat may be present on the first printed circuit board 331. The surface heating temperature of the first housing 321 may be higher than the surface heating temperature of the second housing 322 due to a heat source (e.g., the AP 415 of FIG. 5) disposed on the first printed circuit board 331. A heat dissipation structure for transferring heat generated in the first housing 321 to the second housing 322 through the hinge structure 340 may be included to prevent/reduce the surface heating temperature from increasing relative to the volume of the first housing 321. Hereinafter, the configuration and structure of the heat dissipation structure is described in detail.

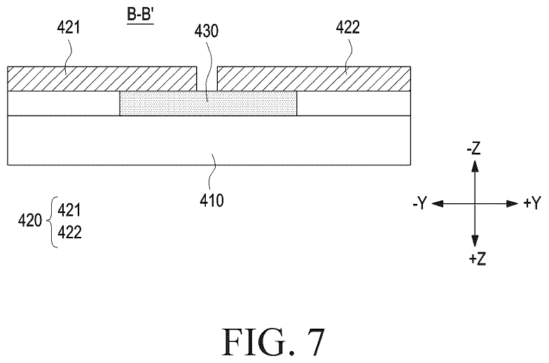

FIG. 5 is a diagram illustrating a flexible display 410 and a heat dissipation structure, and illustrating a heat transfer path according to various embodiments. FIGS. 6 and 7 are cross-sectional views illustrating a portion of the display 410 and the heat dissipation structure of FIG. 5 taken along line B-B′ according to various embodiments.

Referring to FIGS. 5 to 7, an electronic device (e.g., the electronic device 101 of FIG. 2) may include a housing (e.g., the foldable housing 321, 322 of FIG. 4), a flexible display 410, a heat dissipation layer 420, and a heat conductive layer 430. The configuration of the flexible display 410 of FIGS. 5 to 7 may be identical in whole or part to the configuration of the display 310 of FIG. 4. The structure of FIGS. 5 to 7 may be selectively combined with the structure of FIGS. 2 to 4.

According to an embodiment, the heat dissipation structure may be disposed on the flexible display 410. For example, at least a portion of the heat dissipation structure may be disposed between the flexible display 410 and the hinge (e.g., the hinge structure 340 of FIG. 4). For example, at least a portion of the heat dissipation structure may be disposed between the flexible display 410 and the bracket assembly (e.g., the bracket assembly 325 of FIG. 4). However, the position of the heat dissipation structure is not limited and may be varied in design.

According to an embodiment, the heat dissipation structure may include a flat area 403 including a first flat area 401 disposed in the first housing (e.g., the first housing 321 of FIG. 4) and a second flat area 402 disposed in the second housing (e.g., the second housing 322 of FIG. 4), and a folding area 404 located between the first flat area 401 and the second flat area 402 and configured such that at least a portion thereof is folded or unfolded.

According to an embodiment, the heat dissipation structure may include a heat dissipation layer 420 stacked above the flexible display 410 (e.g., in a −Z-axis direction), and a heat conductive layer 430 stacked with at least a portion of the heat dissipation layer 420. According to an embodiment, the heat dissipation layer 420 may include a first heat dissipation layer 421 located in the first housing (e.g., the first housing 321 of FIG. 4), and a second heat dissipation layer 422 located in the second housing (e.g., the second housing 322 of FIG. 4). The first heat dissipation layer 421 and the second heat dissipation layer 422 may be spaced apart from each other. The first heat dissipation layer 421 and the second heat dissipation layer 422 may not be directly thermally coupled. For example, the first heat dissipation layer 421 and the second heat dissipation layer 422 may be disposed on substantially the same plane with respect to the Z-axis when the first housing (e.g., the first housing 321 of FIG. 4) is in an unfolded state with respect to the second housing (e.g., the second housing 322 of FIG. 4). According to an embodiment, the heat dissipation layer 420 may be disposed on the flat area 403. The heat dissipation layer 420 may not be disposed on the folding area 404. According to an embodiment, at least a portion of the first heat dissipation layer 421 may be disposed on the first flat area 401. At least a portion of the second heat dissipation layer 422 may be disposed on the second flat area 402.

According to an embodiment, the first heat dissipation layer 421 and the second heat dissipation layer 422 may include a heat dissipation sheet (e.g., graphite) for transferring heat. For example, the thermal conductivity of the heat dissipation layer 420 may be about 1000 W/mK or more. For example, the elongation rate of the heat dissipation layer 420 may be about 1% or more and 2% or less. The elongation rate may be defined as a ratio where an object such as a metal or a heat dissipation sheet stretches without breaking in a tensile test or the like. Since the heat dissipation layer 420 has a low elongation rate, fracture may occur when disposed on the folding area 404, so the heat dissipation layer 420 may be disposed on the flat area 403.

According to an embodiment, the heat conductive layer 430 may thermally couple the first heat dissipation layer 421 and the second heat dissipation layer 422. At least a portion of the heat conductive layer 430 may be stacked with at least a portion of the heat dissipation layer 420 (e.g., the first heat dissipation layer 421 or the second heat dissipation layer 422). One end of the heat conductive layer 430 in a left direction (e.g., the −Y-axis direction of FIG. 6) may be stacked with at least a portion of the first heat dissipation layer 421, and the other end of the heat conductive layer 430 in a right direction (e.g., the +Y-axis direction of FIG. 6) may be stacked with at least a portion of the second heat dissipation layer 422. For example, a central portion of the heat conductive layer 430 with respect to a direction perpendicular to the folding axis (e.g., the Y-axis direction) may not be stacked with the heat dissipation layer 420. For example, since the first heat dissipation layer 421 and the second heat dissipation layer 422 are spaced apart, the central portion of the heat conductive layer 430 may correspond to an empty space between the first heat dissipation layer 421 and the second heat dissipation layer 422. For example, one end in contact with the first heat dissipation layer 421 and the other end in contact with the second heat dissipation layer 422 may be portions substantially in contact with the first heat dissipation layer 421 and/or the second heat dissipation layer 422, and the central portion may be a section substantially stretched.

According to an embodiment, at least a portion of the heat conductive layer 430 may be disposed on the folding area 404. According to an embodiment, the heat conductive layer 430 may be a material with a high elongation rate. For example, the elongation rate of the heat conductive layer 430 may be higher than the elongation rate of the heat dissipation layer 420. For example, the elongation rate of the heat conductive layer 430 may be about 10% or more. By disposing the heat conductive layer 430 with a high elongation rate on the folding area 404, fracture of the heat dissipation structure occurring due to a length difference when the foldable electronic device (e.g., the electronic device 101 of FIG. 2) is in an unfolded state and when the electronic device (e.g., the electronic device 101 of FIG. 2) is in a folded state may be prevented/reduced. According to an embodiment, the thermal conductivity of the heat conductive layer 430 may be lower than thermal conductivity of the heat dissipation layer 420. For example, the thermal conductivity of the heat conductive layer 430 may be about 50 W/mK or less. For example, the thermal conductivity of the heat conductive layer 430 may be about 20 W/mK or more and 50 W/mK or less.

An embodiment according to the disclosure may increase thermal conductivity of the foldable electronic device (e.g., the electronic device 101 of FIG. 2) and prevent/reduce fracture of the heat dissipation structure by disposing the heat dissipation layer 420 with high thermal conductivity on the flat area 403 of the foldable electronic device (e.g., the electronic device 101 of FIG. 2) and disposing the heat conductive layer 430 with a high elongation rate on the folding area 404. According to an embodiment, the heat conductive layer 430 may include a material in which heat conductive heat dissipation particles are added to a material with a high elongation rate such as polymer or polyurethane. For example, the heat dissipation particles may be particles such as graphene or aluminum oxide (Al2O3).

According to an embodiment, heat generated in the first housing (e.g., the first housing 321 of FIG. 4) may be transferred (e.g., sequentially) to the second housing (e.g., the second housing 322 of FIG. 4) through the first heat dissipation layer 421, the heat conductive layer 430, and the second heat dissipation layer 422. For example, heat generated in the first housing (e.g., the first housing 321 of FIG. 4) (e.g., heat generated by the heat source AP) may be transferred to the first heat dissipation layer 421 before moving to the flexible display 410 disposed in the first housing (e.g., the first housing 321 of FIG. 4), heat transferred to the first heat dissipation layer 421 may be transferred to the heat conductive layer 430, and heat transferred to the heat conductive layer 430 may be transferred to the second heat dissipation layer 422 and may move to the second housing (e.g., the second housing 322 of FIG. 4).

According to an embodiment, referring to FIG. 6, the heat dissipation layer 420 (e.g., the first heat dissipation layer 421 or the second heat dissipation layer 422) may be disposed above the flexible display 410 (e.g., in the −Z-axis direction), and the heat conductive layer 430 may be disposed above the heat dissipation layer 420. The heat dissipation layer 420 may be disposed between the flexible display 410 and the heat conductive layer 430. According to an embodiment, referring to FIG. 7, the heat conductive layer 430 may be disposed above the flexible display 410 (e.g., in the −Z-axis direction), and the heat dissipation layer 420 (e.g., the first heat dissipation layer 421 or the second heat dissipation layer 422) may be disposed above the heat conductive layer 430 (e.g., in the −Z-axis direction). For example, the heat conductive layer 430 may be disposed between the flexible display 410 and the heat dissipation layer 420. According to an embodiment, the heat conductive layer 430 may be disposed between the first heat dissipation layer 421 and the second heat dissipation layer 422. The first heat dissipation layer 421, the second heat dissipation layer 422, and the heat conductive layer 430 may be disposed on substantially the same plane (not illustrated). The stacking order of the heat dissipation layer 420 and the heat conductive layer 430 may be changed and may be varied in design.

According to an embodiment, the heat dissipation structure with the heat conductive layer 430 added may have a surface temperature of the (e.g., the first housing 321 of FIG. 4) about 0.5 degrees lower compared to a heat dissipation structure to which no heat conductive layer is applied. For example, the surface temperature of the first housing including the heat dissipation structure to which no heat conductive layer is applied may be 47.3 degrees, and the surface temperature of the first housing (e.g., the first housing 321 of FIG. 4) including the heat dissipation structure according to the disclosure to which the heat conductive layer 430 is applied may be 46.9 degrees.

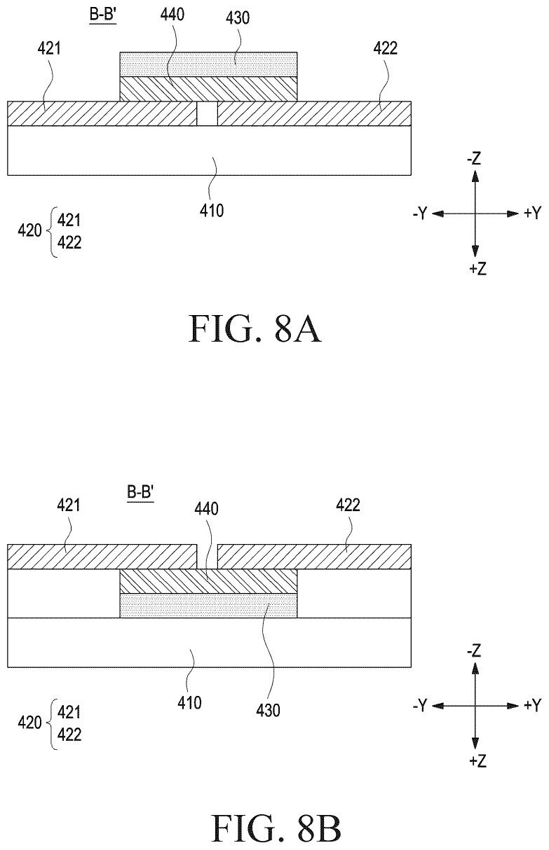

FIGS. 8A and 8B are cross-sectional views illustrating a portion of the heat dissipation structure including the anti-stick layer 440 of FIG. 5 taken along line B-B′ according to various embodiments.

Referring to FIGS. 8A and 8B, an electronic device (e.g., the electronic device 101 of FIG. 2) may include a flexible display 410 and a heat dissipation structure. For example, the heat dissipation structure may include a heat dissipation layer 420, a heat conductive layer 430, and an anti-stick layer 440. The configuration of the flexible display 410, the heat dissipation layer 420, and the heat conductive layer 430 of FIGS. 8A to 8B may be identical in whole or part to the configuration of the display 310, the heat dissipation layer 420, and the heat conductive layer 430 of FIGS. 5 to 7. The structure of FIGS. 8A and 8B may be selectively combined with the structure of FIGS. 5 to 7.

According to an embodiment, the heat dissipation structure may further include an anti-stick layer 440 to prevent and/or reduce a substantial stretchable area from becoming narrower than the area of the heat conductive layer 430 due to the heat conductive layer 430 and the heat dissipation layer 420 being stuck together. According to an embodiment, the anti-stick layer 440 may be disposed between the heat conductive layer 430 and the heat dissipation layer 420. The anti-stick layer 440 may be attached to the heat conductive layer 430. The anti-stick layer 440 may correspond in size and/or position to the heat conductive layer 430. For example, the length (e.g., the Y-axis direction length of FIG. 8A) and/or position of the anti-stick layer 440 may be substantially the same as those of the heat conductive layer 430. The anti-stick layer 440 may be disposed on the folding area 404.

According to an embodiment, the anti-stick layer 440 may have a high elongation rate. For example, the elongation rate of the anti-stick layer 440 may be higher than the elongation rate of the heat dissipation layer 420. According to an embodiment, the anti-stick layer 440 may have a low adhesive force. The anti-stick layer 440 may not be adhered, bonded, and/or stuck to the heat dissipation layer 420. According to an embodiment, the anti-stick layer 440 may be a matte material with a low friction force. The anti-stick layer 440 may include, e.g., thermoplastic polyurethane (TPU). According to an embodiment, when the foldable electronic device (e.g., the electronic device 101 of FIG. 2) changes from an unfolded state to a folded state, one surface of the anti-stick layer 440 facing the heat dissipation layer 420 may slide with respect to the heat dissipation layer 420.

According to an embodiment, when the heat dissipation layer 420 is disposed between the flexible display 410 and the heat conductive layer 430 according to FIG. 6, the heat dissipation layer 420 (e.g., the first heat dissipation layer 421 or the second heat dissipation layer 422) may be disposed above the flexible display 410 (e.g., in the −Z-axis direction), the anti-stick layer 440 may be disposed above the heat dissipation layer 420 (e.g., in the −Z-axis direction), and the heat conductive layer 430 may be disposed above the anti-stick layer 440 (e.g., in the −Z-axis direction) (see FIG. 8A). According to an embodiment, referring to FIG. 8B, when the heat conductive layer 430 is disposed between the flexible display 410 and the heat dissipation layer 420, the heat conductive layer 430 may be disposed above the flexible display 410 (e.g., in the −Z-axis direction), the anti-stick layer 440 may be disposed above the heat conductive layer 430 (e.g., in the −Z-axis direction), and the heat dissipation layer 420 (e.g., the first heat dissipation layer 421 or the second heat dissipation layer 422) may be disposed above the anti-stick layer 440 (e.g., in the −Z-axis direction). The stacking order of the heat dissipation layer 420 and the heat conductive layer 430 may be changed and may be varied in design.

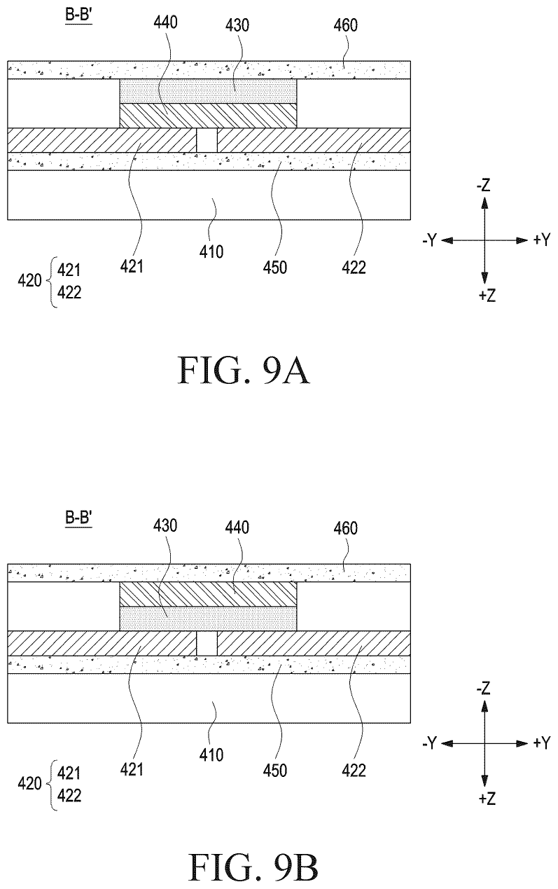

FIGS. 9A and 9B are cross-sectional views illustrating a portion of the heat dissipation structure including the surface protective layer 450, 460 of FIG. 5 taken along line B-B′ according to various embodiments.

Referring to FIGS. 9A and 9B, an electronic device (e.g., the electronic device 101 of FIG. 2) may include a flexible display 410 and a heat dissipation structure. For example, the heat dissipation structure may include a heat dissipation layer 420, a heat conductive layer 430, an anti-stick layer 440, or a surface protective layer 450, 460. The configuration of the flexible display 410, the heat dissipation layer 420, the heat conductive layer 430, and the anti-stick layer 440 of FIGS. 9A to 9B may be identical in whole or part to the configuration of the display 310, the heat dissipation layer 420, the heat conductive layer 430, and the anti-stick layer 440 of FIGS. 5 to 8B. The structure of FIGS. 9A and 9B may be selectively combined with the structure of FIGS. 5 to 8B.

According to an embodiment, the heat dissipation structure may further include a surface protective layer 450, 460 on the surface of the heat dissipation structure so that the heat dissipation layer 420 and/or the heat conductive layer 430 are not exposed.

According to an embodiment, graphite included in the heat dissipation layer 420 may be a conductive material that is easily fragmented and scatters in dust form when externally exposed. When the heat dissipation layer 420 is exposed to the outside of the heat dissipation structure and scatters in dust form, the function of the heat dissipation layer 420 may be weakened, usability may be degraded and, when foreign objects is stuck or trapped, the electronic device (e.g., the electronic device 101 of FIG. 2) including the heat dissipation layer 420 may be damaged. To prevent and/or reduce this, according to an embodiment, a surface protective layer 450, 460 may be additionally disposed so that the heat dissipation layer 420 and/or the heat conductive layer 430 are not exposed to the outside of the heat dissipation structure. For example, the surface protective layer 450, 460 may include a first protective layer 450 facing the flexible display 410, and/or a second protective layer 460 facing the hinge (e.g., the hinge structure 340 of FIG. 4). For example, either the first protective layer 450 or the second protective layer 460 may be omitted. For example, according to an embodiment, the heat dissipation structure may include the first protective layer 450 and may not include the second protective layer 460. According to an embodiment, the surface protective layer 450, 460 may be disposed on the folding area 404 and/or the flat area 403. For example, the surface protective layer 450, 460 may be integrally disposed on the folding area 404 and the flat area 403.

According to an embodiment, the surface protective layer 450, 460 may have a high elongation rate. For example, the elongation rate of the surface protective layer 450, 460 may be higher than the elongation rate of the heat dissipation layer 420. According to an embodiment, the surface protective layer 450, 460 may be a material that does not generate debris even when the surface is damaged and/or impaired. The surface protective layer 450, 460 may include, e.g., thermoplastic polyurethane (TPU).

According to an embodiment, when the heat dissipation layer 420 is disposed between the flexible display 410 and the heat conductive layer 430 according to FIG. 8A, the first protective layer 450 may be disposed above the flexible display 410 (e.g., in the −Z-axis direction), the heat dissipation layer 420 (e.g., the first heat dissipation layer 421 or the second heat dissipation layer 422) may be disposed above the first protective layer 450 (e.g., in the −Z-axis direction), the anti-stick layer 440 may be disposed above the heat dissipation layer 420 (e.g., in the −Z-axis direction), the heat conductive layer 430 may be disposed above the anti-stick layer 440 (e.g., in the −Z-axis direction), and the second protective layer 460 may be disposed above the heat conductive layer 430 (e.g., in the −Z-axis direction) (see FIG. 9A). For example, the second protective layer 460 may be located between the heat conductive layer 430 and the hinge. According to an embodiment, when the heat conductive layer 430 is disposed between the flexible display 410 and the heat dissipation layer 420 according to FIG. 8B, the first protective layer 450 may be disposed above the flexible display 410 (e.g., in the −Z-axis direction), the heat conductive layer 430 may be disposed above the first protective layer 450 (e.g., in the −Z-axis direction), the anti-stick layer 440 may be disposed above the heat conductive layer 430 (e.g., in the −Z-axis direction), the heat dissipation layer 420 (e.g., the first heat dissipation layer 421 or the second heat dissipation layer 422) may be disposed above the anti-stick layer 440 (e.g., in the −Z-axis direction), and the second protective layer 460 may be disposed above the heat dissipation layer 420 (e.g., in the −Z-axis direction) (see FIG. 9B). For example, the second protective layer 460 may be located between the heat dissipation layer 420 and the hinge (e.g., the hinge structure 340 of FIG. 4). The stacking order of the heat dissipation layer 420 and the heat conductive layer 430 may be changed and may be varied in design. Hereinafter, for convenience of description, description will be made with reference to FIG. 9B in which the heat conductive layer 430 is disposed between the flexible display 410 and the heat dissipation layer 420. However, this may be substantially equally applied even when the heat dissipation layer 420 is disposed between the flexible display 410 and the heat conductive layer 430.

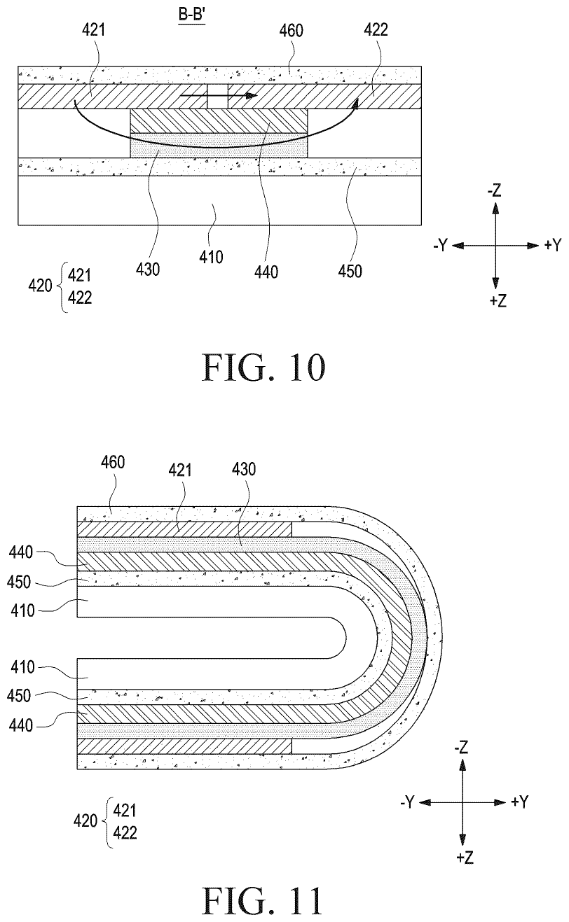

FIG. 10 is a cross-sectional view illustrating a portion of the heat dissipation structure of FIG. 5 taken along line B-B′ when the electronic device (e.g., the electronic device 101 of FIG. 2) is in an unfolded state according to various embodiments. FIG. 11 is a cross-sectional view illustrating a portion of the heat dissipation structure of FIG. 5 taken along line B-B′ when the electronic device (e.g., the electronic device 101 of FIG. 2) is in a folded state according to various embodiments.

Referring to FIGS. 10 and 11, an electronic device (e.g., the electronic device 101 of FIG. 2) may include a flexible display 410 and a heat dissipation structure. For example, the heat dissipation structure may include a heat dissipation layer 420, a heat conductive layer 430, an anti-stick layer 440, or a surface protective layer 450, 460. The configuration of the flexible display 410, the heat dissipation layer 420, the heat conductive layer 430, and the anti-stick layer 440 of FIGS. 10 and 11 may be substantially the same as all or some of the configuration of the display 310, the heat dissipation layer 420, the heat conductive layer 430, and the anti-stick layer 440 of FIGS. 5 to 9B. The structure of FIGS. 10 and 11 may be selectively combined with the structure of FIGS. 5 to 9B.

According to an embodiment, referring to FIG. 10, when the electronic device (e.g., the electronic device 101 of FIG. 2) is in an unfolded state, when the first housing (e.g., the first housing 321 of FIG. 4) rotates with respect to the second housing (e.g., the second housing 322 of FIG. 4) and an angle between the first housing (e.g., the first housing 321 of FIG. 4) and the second housing (e.g., the second housing 322 of FIG. 4) is 180 degrees, the heat dissipation structure may be in a state in which no stretching occurs. According to an embodiment, when a lot of heat is generated in the first housing (e.g., the first housing 321 of FIG. 4), and the internal temperature of the first housing (e.g., the first housing 321 of FIG. 4) is higher than that of the second housing (e.g., the second housing 322 of FIG. 4), most of the heat in the first housing (e.g., the first housing 321 of FIG. 4) may be transferred to the first heat dissipation layer 421 disposed in the first housing (e.g., the first housing 321 of FIG. 4), heat from the first heat dissipation layer 421 may be transferred to the heat conductive layer 430, and heat from the heat conductive layer 430 may be transferred to the second heat dissipation layer 422. According to an embodiment, heat generated in the first housing (e.g., the first housing 321 of FIG. 4) may be transferred sequentially to the second housing (e.g., the second housing 322 of FIG. 4) through the first heat dissipation layer 421, the heat conductive layer 430, and the second heat dissipation layer 422. For example, heat generated in the first housing (e.g., the first housing 321 of FIG. 4) (e.g., heat generated by the heat source AP) may be transferred to the first heat dissipation layer 421 before moving to the flexible display 410 disposed in the first housing (e.g., the first housing 321 of FIG. 4), heat transferred to the first heat dissipation layer 421 may be transferred to the heat conductive layer 430, and heat transferred to the heat conductive layer 430 may be transferred to the second heat dissipation layer 422 and may move to the second housing (e.g., the second housing 322 of FIG. 4).

According to an embodiment, a small amount of heat in the first housing (e.g., the first housing 321 of FIG. 4) may be transferred to the first heat dissipation layer 421 disposed in the first housing (e.g., the first housing 321 of FIG. 4), and heat from the first heat dissipation layer 421 may be transferred to the second heat dissipation layer 422 disposed to be spaced apart.

According to an embodiment, referring to FIG. 11, when the electronic device (e.g., the electronic device 101 of FIG. 2) is in a folded state, when the first housing (e.g., the first housing 321 of FIG. 4) rotates with respect to the second housing (e.g., the second housing 322 of FIG. 4) and an angle between the first housing (e.g., the first housing 321 of FIG. 4) and the second housing (e.g., the second housing 322 of FIG. 4) is about 0 degrees, the folding area 404 of the heat dissipation structure may be stretched. When the electronic device (e.g., the electronic device 101 of FIG. 2) is in a folded state, the length of the folding area 404 of the heat dissipation structure may be longer than the length of the folding area 404 of the heat dissipation structure when the electronic device (e.g., the electronic device 101 of FIG. 2) is in an unfolded state. For example, the heat dissipation layer 420 located in the flat area 403 may not be stretched. For example, the distance between the first heat dissipation layer 421 and the second heat dissipation layer 422 may increase. For example, a space between the first heat dissipation layer 421 and the second heat dissipation layer 422 may be an air layer 4002. For example, the air layer 4002 may refer to an empty space. For example, the length of the anti-stick layer 440, the heat conductive layer 430, and the surface protective layer 450, 460 (e.g., the first protective layer 450 or the second protective layer 460) at least partially located on the folding area 404 may increase.

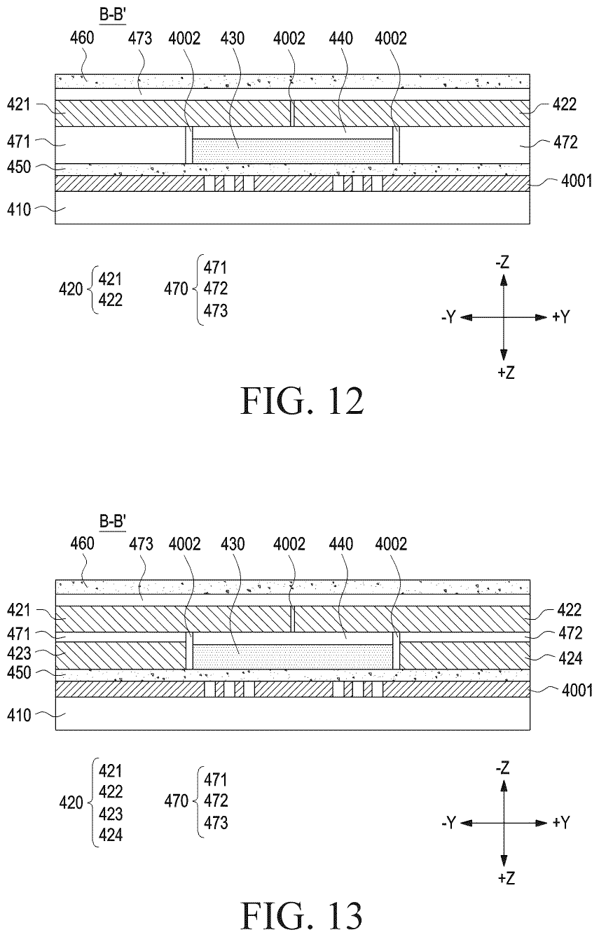

FIG. 12 is a cross-sectional view illustrating a portion of the heat dissipation structure including an adhesive layer 470 taken along line B-B′ according to various embodiments.

Referring to FIG. 12, an electronic device (e.g., the electronic device 101 of FIG. 2) may include a flexible display 410 and a heat dissipation structure. For example, the heat dissipation structure may include a heat dissipation layer 420, a heat conductive layer 430, an anti-stick layer 440, a surface protective layer 450, 460, and an adhesive layer 470. The configuration of the flexible display 410, the heat dissipation layer 420, the heat conductive layer 430, the anti-stick layer 440, and the surface protective layer 450, 460 of FIG. 12 may be identical in whole or part to the configuration of the display 310, the heat dissipation layer 420, the heat conductive layer 430, the anti-stick layer 440, and the surface protective layer 450, 460 of FIGS. 5 to 11. The structure of FIG. 12 may be selectively combinable with the structures of FIGS. 5 to 11.

According to an embodiment, at least a portion of the heat conductive layer 430 and/or the anti-stick layer 440 may be located on the folding area 404 of the heat dissipation structure. The heat dissipation structure may further include a first adhesive layer 471, 472 disposed on a side (e.g., a side in the Y-axis direction of FIG. 12) of the heat conductive layer 430 and/or the anti-stick layer 440 for adhering the heat dissipation layer 420 and the first protective layer 450. The first adhesive layer 471, 472 may be stacked with at least a portion of the heat dissipation layer 420 and may be disposed side by side with the heat conductive layer 430 and/or the anti-stick layer 440. For example, the first adhesive layer 471, 472 may include a 1-1th adhesive layer 471 disposed on the first flat area 401 and located between the first heat dissipation layer 421 and the first protective layer 450, and/or a 1-2th adhesive layer 472 disposed on the second flat area 402 and located between the second heat dissipation layer 422 and the first protective layer 450.

According to an embodiment, the heat dissipation structure may further include a second adhesive layer 473 disposed between at least a portion of the heat dissipation layer 420 and at least a portion of the second protective layer 460 for adhering the heat dissipation layer 420 and the second protective layer 460. One surface of the second adhesive layer 473 facing the flexible display 410 may face the first heat dissipation layer 421 and the second heat dissipation layer 422, and the other surface facing the opposite direction from the one surface may face the second protective layer 460.

According to an embodiment, the adhesive layer 470 (e.g., the first adhesive layer 471, 472, or the second adhesive layer 473) may have a high elongation rate. For example, the elongation rate of the adhesive layer 470 may be higher than the elongation rate of the heat dissipation layer 420. For example, the adhesive layer 470 may include a pressure sensitive adhesive (PSA).

According to an embodiment, the heat dissipation structure may further include a lattice structure layer 4001 between the flexible display 410 and the surface protective layer (e.g., the first protective layer 450).

According to an embodiment, the heat dissipation structure may further include an air layer 4002 located between each component included in the heat dissipation structure. For example, the air layer 4002 may refer to an empty space formed between each component forming the heat dissipation structure. For example, an air layer 4002 may be formed between the first adhesive layer 471 and the heat conductive layer 430, and between the heat conductive layer 430 and the second adhesive layer 472. For example, an air layer 4002 may be formed between the first heat dissipation layer 421 and the second heat dissipation layer 422.

FIG. 13 is a cross-sectional view illustrating a portion of the heat dissipation structure including a heat dissipation layer 420 taken along line B-B′ according to various embodiments.

Referring to FIG. 13, an electronic device (e.g., the electronic device 101 of FIG. 2) may include a flexible display 410 and a heat dissipation structure. For example, the heat dissipation structure may include a heat dissipation layer 420, a heat conductive layer 430, an anti-stick layer 440, a surface protective layer 450, 460, and an adhesive layer 470. The configuration of the flexible display 410, the heat dissipation layer 420, the heat conductive layer 430, the anti-stick layer 440, the surface protective layer 450, 460, and the adhesive layer 470 of FIG. 13 may be identical in whole or part to the configuration of the display 310, the heat dissipation layer 420, the heat conductive layer 430, the anti-stick layer 440, the surface protective layer 450, 460, and the adhesive layer 470 of FIGS. 5 to 12. The structure of FIG. 13 may be selectively combinable with the structures of FIGS. 5 to 12.

According to an embodiment, the heat dissipation structure may further include a heat dissipation layer 420 (e.g., a third heat dissipation layer 423 or a fourth heat dissipation layer 424) disposed on a side (e.g., in the Y-axis direction) of the heat conductive layer 430 and/or the anti-stick layer 440 for enhancing thermal conductivity of the flat area 403. The heat dissipation layer 420 may further include a third heat dissipation layer 423 stacked with at least a portion of the first heat dissipation layer 421 and disposed side by side with the heat conductive layer 430, and a fourth heat dissipation layer 424 stacked with at least a portion of the second heat dissipation layer 422 and disposed side by side with the heat conductive layer 430. For example, the third heat dissipation layer 423 may be disposed between the first heat dissipation layer 421 and the first protective layer 450. For example, the fourth heat dissipation layer 424 may be disposed between the second heat dissipation layer 422 and the first protective layer 450. According to an embodiment, the third heat dissipation layer 423 and/or the fourth heat dissipation layer 424 may be disposed on the flat area 403 of the electronic device (e.g., the electronic device 101 of FIG. 2). For example, the third heat dissipation layer 423 may be disposed on the first flat area 401, and the fourth heat dissipation layer 424 may be disposed on the second flat area 402.

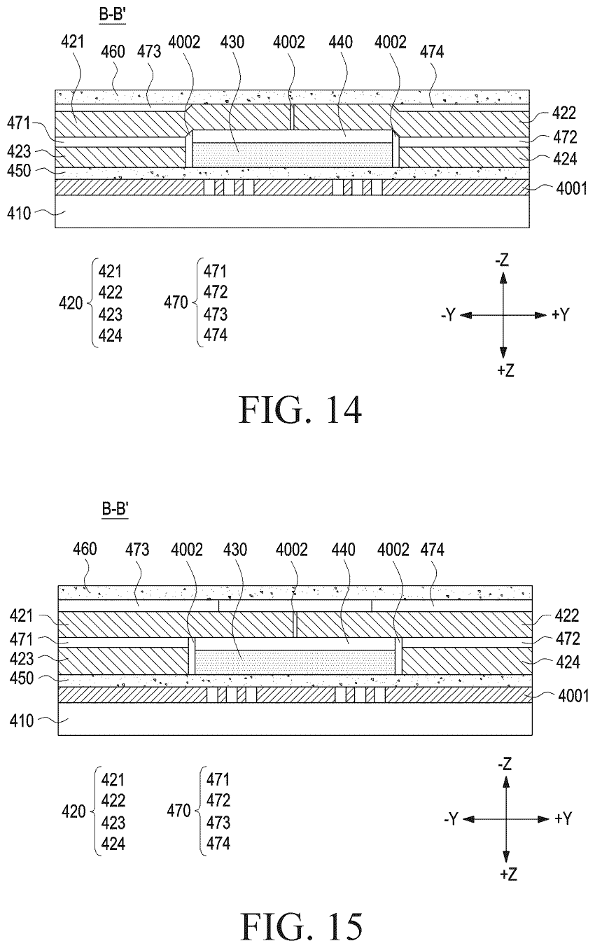

FIG. 14 is a cross-sectional view illustrating a portion of the heat dissipation structure including the heat dissipation layer 421, 422 with a step taken along line B-B′ according to various embodiments. FIG. 15 is a cross-sectional view illustrating a portion of the heat dissipation structure including a heat dissipation layer 420 taken along line B-B′ according to various embodiments.

Referring to FIGS. 14 and 15, an electronic device (e.g., the electronic device 101 of FIG. 2) may include a flexible display 410 and a heat dissipation structure. For example, the heat dissipation structure may include a heat dissipation layer 420, a heat conductive layer 430, an anti-stick layer 440, a surface protective layer 450, 460, and an adhesive layer 470. The configuration of the flexible display 410, the heat dissipation layer 420, the heat conductive layer 430, the anti-stick layer 440, the surface protective layer 450, 460, and the adhesive layer 470 of FIGS. 14 and 15 may be identical in whole or part to the configuration of the display 310, the heat dissipation layer 420, the heat conductive layer 430, the anti-stick layer 440, the surface protective layer 450, 460, and the adhesive layer 470 of FIGS. 5 to 13. The structure of FIGS. 14 and 15 may be selectively combined with the structure of FIGS. 5 to 13.

According to an embodiment, a second adhesive layer 473, 474 may be disposed between at least a portion of the heat dissipation layer 420 and at least a portion of the second protective layer 460 for adhering the heat dissipation layer 420 and the second protective layer 460. According to an embodiment, the second adhesive layer 473 may be integrally formed referring to FIG. 12. According to an embodiment, referring to FIG. 14, the second adhesive layer 473, 474 may be located on the flat area 403 of the heat dissipation structure. The second adhesive layer 473, 474 may not be located on the folding area 404. For example, the second adhesive layer 473, 474 may include a 2-1th adhesive layer 473 disposed between a portion of the first heat dissipation layer 421 located on the first flat area 401 and the second protective layer 460, and/or a 2-2th adhesive layer 474 disposed between a portion of the second heat dissipation layer 422 located on the second flat area 402 and the second protective layer 460. This is because the elongation rate may decrease when the adhesive layer 470 is disposed on the folding area 404.

According to an embodiment, the folding area 404 may not include the second adhesive layer 473, 474. For example, referring to FIG. 15, a space between the 2-1th adhesive layer 473 and the 2-2th adhesive layer 474 may be an empty space.

According to an embodiment, referring to FIG. 14, the first heat dissipation layer 421 and/or the second heat dissipation layer 422 may include a step with different heights in the Z-axis direction. For example, the Z-axis direction position of a portion of the first heat dissipation layer 421 located above the third heat dissipation layer 423 and/or the 1-1th adhesive layer 471 (e.g., in the −Z-axis direction) may be different from that of another portion of the first heat dissipation layer 421 located above the heat conductive layer 430 and/or the anti-stick layer 440. For example, the first heat dissipation layer 421 located above the heat conductive layer 430 and/or the anti-stick layer 440 may be located further in the +Z direction by a designated length than the first heat dissipation layer 421 located above the third heat dissipation layer 423 and/or the 1-1th adhesive layer 471. This may be because the second adhesive layer 470 is not included in the folding area 404, and the Z-axis direction thickness of the heat conductive layer 430 is formed relatively high.

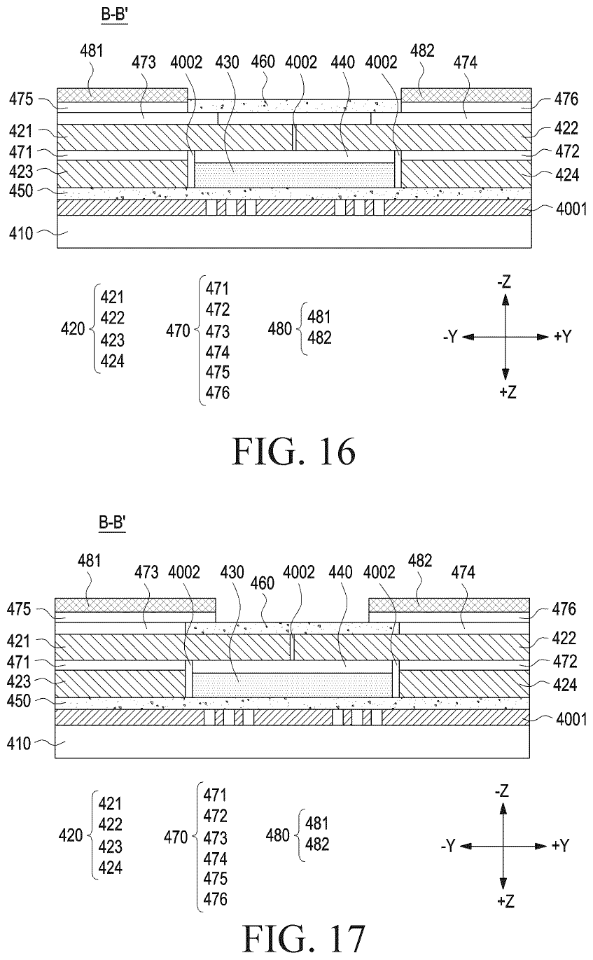

FIGS. 16 and 17 are cross-sectional views illustrating a portion of the heat dissipation structure further including a protective film 480 taken along line B-B′ according to various embodiments.

Referring to FIGS. 16 and 17, an electronic device (e.g., the electronic device 101 of FIG. 2) may include a flexible display 410 and a heat dissipation structure. For example, the heat dissipation structure may include a heat dissipation layer 420, a heat conductive layer 430, an anti-stick layer 440, a surface protective layer 450, 460, and an adhesive layer 470. The configuration of the flexible display 410, the heat dissipation layer 420, the heat conductive layer 430, the anti-stick layer 440, the surface protective layer 450, 460, and the adhesive layer 470 of FIGS. 16 and 17 may be identical in whole or part to the configuration of the display 310, the heat dissipation layer 420, the heat conductive layer 430, the anti-stick layer 440, the surface protective layer 450, 460, and the adhesive layer 470 of FIGS. 5 to 15. The structure of FIGS. 16 and 17 may be selectively combined with the structure of FIGS. 5 to 15.

According to an embodiment, at least a portion of the second protective layer 460 may be formed on the folding area 404. According to an embodiment, the second protective layer 460 may be formed on the folding area 404.

According to an embodiment, the heat dissipation structure may further include a protective film 480 for protecting the heat dissipation structure on the flat area 403 where the second protective layer 460 is not located. For example, the protective film 480 may include a first protective film 481 disposed on the first flat area 401 and connected to one end of the second protective layer 460, and a second protective film 482 disposed on the second flat area 402 and connected to the other end of the second protective layer 460. The protective film 480 may be a material such as polyester film (PET), polyethylene terephthalate film (PEN), or polyimide film (PI).

According to an embodiment, the heat dissipation structure may further include a third adhesive layer 475, 476 for attaching the protective film 480 and the heat dissipation layer 420. For example, the third adhesive layer 475, 476 may include a 3-1th adhesive layer 475 disposed between the first protective film 481 and the first heat dissipation layer 421, and/or a 3-2th adhesive layer 476 disposed between the second protective film 482 and the second heat dissipation layer 422.

According to an embodiment, referring to FIG. 16, one end of the second protective layer 460 may contact the 3-1th adhesive layer 475, and the other end of the second protective layer 460 may contact the 3-2th adhesive layer 476. The second protective layer 460 may be disposed above the second adhesive layer 473, 474 (e.g., in the −Z-axis direction) and may be disposed on substantially the same plane as the third adhesive layer 475, 476.

According to an embodiment, referring to FIG. 17, the second protective layer 460 may be disposed on substantially the same plane as the second adhesive layer 473, 474. For example, the empty space between the 2-1th adhesive layer 473 and the 2-2th adhesive layer 474 may be removed, and the second protective layer 460 may be disposed between the 2-1th adhesive layer 473 and the 2-2th adhesive layer 474.

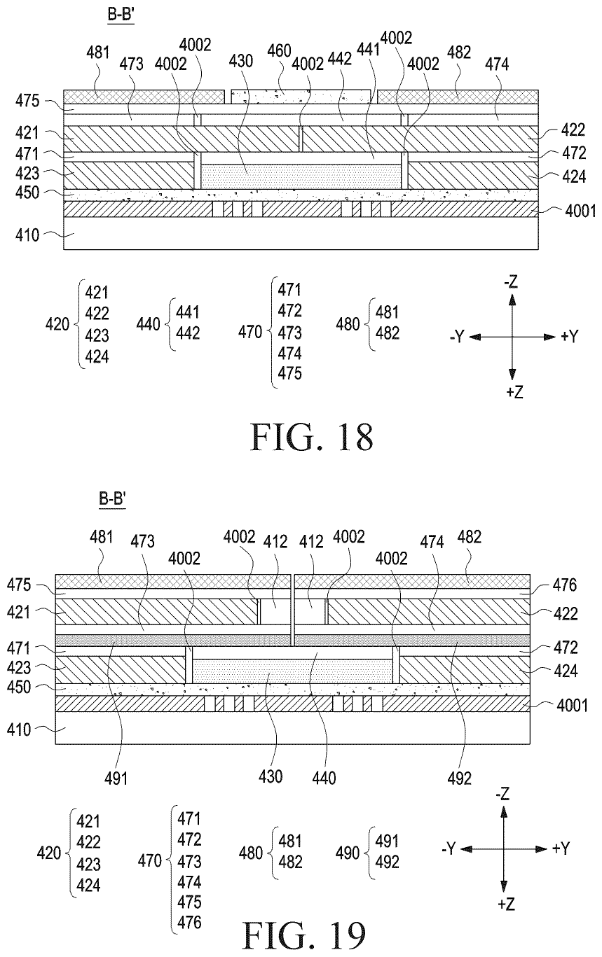

FIG. 18 is a cross-sectional view illustrating a portion of the heat dissipation structure further including a second anti-stick layer 442 taken along line B-B′ according to various embodiments.

Referring to FIG. 18, an electronic device (e.g., the electronic device 101 of FIG. 2) may include a flexible display 410 and a heat dissipation structure. For example, the heat dissipation structure may include a heat dissipation layer 420, a heat conductive layer 430, an anti-stick layer 440, a surface protective layer 450, 460, and an adhesive layer 470. The configuration of the flexible display 410, the heat dissipation layer 420, the heat conductive layer 430, the anti-stick layer 440, the surface protective layer 450, 460, and the adhesive layer 470 of FIG. 18 may be identical in whole or part to the configuration of the display 310, the heat dissipation layer 420, the heat conductive layer 430, the anti-stick layer 440, the surface protective layer 450, 460, and the adhesive layer 470 of FIGS. 5 to 17. The structure of FIG. 18 may be selectively combinable with the structures of FIGS. 5 to 17.

According to an embodiment, the heat dissipation structure may further include a second anti-stick layer 442 on substantially the same plane as the second adhesive layer 473, 474 to strongly protect fracture of the first heat dissipation layer 421 and the second heat dissipation layer 422 with low elongation rates (for convenience of description, the anti-stick layer 440 illustrated in FIGS. 5 to 17 may be defined as a first anti-stick layer 441). For example, the second anti-stick layer 442 may be disposed between the 2-1th adhesive layer 473 and the 2-2th adhesive layer 474.

According to an embodiment, a third adhesive layer 475 may be disposed above the second anti-stick layer 442 and the second adhesive layer 473, 474. For example, the third adhesive layer 475 may be integrally formed including the folding area 404 and the flat area 403.

According to an embodiment, the second protective layer 460 and the protective film 480 may be disposed above the third adhesive layer 475 (e.g., in the −Z-axis direction). For example, the second protective layer 460 may be disposed on substantially the same plane as the protective film 480. The second protective layer 460 may be disposed on the folding area 404. The first protective film 481 may be disposed on the first flat area 401, and the second protective film 482 may be disposed on the second flat area 402.

FIG. 19 is a cross-sectional view illustrating a portion of a separable heat dissipation structure taken along line B-B′ according to various embodiments.

Referring to FIG. 19, an electronic device (e.g., the electronic device 101 of FIG. 2) may include a flexible display 410 and a heat dissipation structure. For example, the heat dissipation structure may include a heat dissipation layer 420, a heat conductive layer 430, an anti-stick layer 440, a surface protective layer 450, 460, and an adhesive layer 470. The configuration of the flexible display 410, the heat dissipation layer 420, the heat conductive layer 430, the anti-stick layer 440, the surface protective layer 450, 460, and the adhesive layer 470 of FIG. 19 may be identical in whole or part to the configuration of the display 310, the heat dissipation layer 420, the heat conductive layer 430, the anti-stick layer 440, the surface protective layer 450, 460, and the adhesive layer 470 of FIGS. 5 to 17. The structure of FIG. 19 may be selectively combinable with the structures of FIGS. 5 to 18.

According to an embodiment, at least a portion of the heat dissipation structure may be separated as the electronic device (e.g., the electronic device 101 of FIG. 2) is folded.

According to an embodiment, a third anti-stick layer 490 with a low elongation rate may be disposed above the heat conductive layer 430 and/or the anti-stick layer 440 (e.g., in the −Z-axis direction). For example, the third anti-stick layer 490 may be a rigid material with a low elongation rate. The third anti-stick layer 490 may be a non-stretchable material. The third anti-stick layer 490 may include a 3-1th anti-stick layer 491 located in the first housing (e.g., the first housing 321 of FIG. 4), and a 3-2th anti-stick layer 492 located in the second housing (e.g., the second housing 322 of FIG. 4).

According to an embodiment, the heat dissipation structure may further include a 2-1th adhesive layer 473 disposed between the 3-1th anti-stick layer 491 and the first heat dissipation layer 421, and a 2-2th adhesive layer 474 disposed between the 3-2th anti-stick layer 492 and the second heat dissipation layer 422.

According to an embodiment, the heat dissipation structure may include a first protective film 481 located in the first housing (e.g., the first housing 321 of FIG. 4) and stacked with the first heat dissipation layer 421, and a second protective film 482 located in the second housing (e.g., the second housing 322 of FIG. 4) and stacked with the second heat dissipation layer 422.

According to an embodiment, the heat dissipation structure may further include a 3-1th adhesive layer 475 disposed between the first heat dissipation layer 421 and the first protective film 481 and attaching the first heat dissipation layer 421 and the first protective film 481, and a 3-2th adhesive layer 476 disposed between the second heat dissipation layer 422 and the second protective film 482 and attaching the second heat dissipation layer 422 and the second protective film 482.

In an electronic device according to an example embodiment of the disclosure, a first housing (e.g., 321 of FIG. 4), a second housing (e.g., 322 of FIG. 4), a hinge (e.g., the hinge structure 340 of FIG. 4) configured to rotatably couple the first housing and the second housing, a flexible display (e.g., 410 of FIG. 5) configured to vary corresponding to a relative motion of the second housing with respect to the first housing, and a heat dissipation structure at least partially disposed between the flexible display and the hinge may be included. The heat dissipation structure may include a heat dissipation layer (e.g., 420 of FIG. 5) stacked with the flexible display, wherein the heat dissipation layer includes a first heat dissipation layer (e.g., 421 of FIG. 5) located in the first housing, and a second heat dissipation layer (e.g., 422 of FIG. 5) located in the second housing, and a heat conductive layer (e.g., 430 of FIG. 5) stacked with at least a portion of the heat dissipation layer and configured to thermally couple the first heat dissipation layer and the second heat dissipation layer. Heat generated in the first housing may be configured to be transferred sequentially to the second housing through the first heat dissipation layer, the heat conductive layer, and the second heat dissipation layer.

According to an example embodiment, the heat dissipation structure may further include an anti-stick layer (e.g., 440 of FIG. 8A) disposed between the heat conductive layer and the heat dissipation layer.

According to an example embodiment, the heat dissipation structure may include a flat area (e.g., 403 of FIG. 5) including a first flat area (e.g., 401 of FIG. 5) disposed in the first housing and a second flat area (e.g., 402 of FIG. 5) disposed in the second housing, and a folding area (e.g., 404 of FIG. 5) disposed between the first flat area and the second flat area, wherein the first heat dissipation layer is disposed on the first flat area, the second heat dissipation layer is disposed on the second flat area, and at least a portion of the heat conductive layer may be disposed on the folding area.

According to an example embodiment, the first heat dissipation layer and the second heat dissipation layer may be spaced apart from each other.

According to an example embodiment, the heat dissipation layer may be disposed between the heat conductive layer and the flexible display.

According to an example embodiment, the heat conductive layer may be disposed between the heat dissipation layer and the flexible display.

According to an example embodiment, the elongation rate of the heat dissipation layer may be lower than the elongation rate of the heat conductive layer, and thermal conductivity of the heat dissipation layer may be higher than thermal conductivity of the heat conductive layer.

According to an example embodiment, the elongation rate of the heat conductive layer may be 10% or more.

According to an example embodiment, the thermal conductivity of the heat conductive layer may be 50 W/mK or less.

According to an example embodiment, the heat dissipation structure may further include a surface protective layer 450, 460 including a first protective layer (e.g., 450 of FIG. 9A) facing the flexible display and a second protective layer (e.g., 460 of FIG. 9A) facing the hinge.

According to an example embodiment, the heat dissipation structure may further include a first adhesive layer (e.g., 471, 472 of FIG. 12) disposed between at least a portion of the heat dissipation layer and at least a portion of the first protective layer and disposed side by side with the heat conductive layer.

According to an example embodiment, the heat dissipation layer may further include a third heat dissipation layer (e.g., 423 of FIG. 13) stacked with at least a portion of the first heat dissipation layer and disposed side by side with the heat conductive layer, and a fourth heat dissipation layer (e.g., 424 of FIG. 13) stacked with at least a portion of the second heat dissipation layer and disposed side by side with the heat conductive layer.

In an electronic device according to an example embodiment of the disclosure, a first housing, a second housing, a hinge configured to rotatably couple the first housing and the second housing, a flexible display configured to vary corresponding to a relative motion of the second housing with respect to the first housing, and a heat dissipation structure at least partially disposed between the flexible display and the hinge may be included. The heat dissipation structure may include a heat dissipation layer stacked with the flexible display, the heat dissipation layer including a first heat dissipation layer located in the first housing, a second heat dissipation layer located in the second housing, a heat conductive layer stacked with at least a portion of the heat dissipation layer and configured to thermally couple the first heat dissipation layer and the second heat dissipation layer, and an anti-stick layer disposed between the heat conductive layer and the heat dissipation layer. Heat generated in the first housing may be configured to be transferred sequentially to the second housing through the first heat dissipation layer, the heat conductive layer, and the second heat dissipation layer.

According to an example embodiment, the heat dissipation structure may include a flat area including a first flat area disposed above the first housing and a second flat area disposed above the second housing, and a folding area located between the first flat area and the second flat area and configured such that at least a portion thereof is folded or unfolded, wherein the first heat dissipation layer is disposed on the first flat area, the second heat dissipation layer is disposed on the second flat area, and at least a portion of the heat conductive layer may be disposed on the folding area.

According to an example embodiment, the first heat dissipation layer and the second heat dissipation layer may be spaced apart from each other.

According to an example embodiment, the heat dissipation layer may be disposed between the heat conductive layer and the flexible display.

According to an example embodiment, the heat conductive layer may be disposed between the heat dissipation layer and the flexible display.

According to an example embodiment, the elongation rate of the heat dissipation layer may be lower than the elongation rate of the heat conductive layer, and thermal conductivity of the heat dissipation layer may be higher than thermal conductivity of the heat conductive layer.

According to an example embodiment, the elongation rate of the heat conductive layer may be 10% or more.

According to an example embodiment, the thermal conductivity of the heat conductive layer may be 50 W/mK or less.

A hinge portion (e.g., the folding area 404) of a foldable electronic device (e.g., the electronic device 101 of FIG. 2) is foldable, but since there is no structure for transferring heat through the hinge portion, heat may not be dissipated, and the surface heating temperature relative to the volume of the electronic device (e.g., the electronic device 101 of FIG. 2) may increase. When a heat dissipation sheet (e.g., graphite) transferring heat through the hinge portion of the foldable electronic device (e.g., the electronic device 101 of FIG. 2) is disposed, the heat dissipation sheet is folded when the electronic device (e.g., the electronic device 101 of FIG. 2) is in an unfolded state, and the folded heat dissipation sheet may be unfolded when the electronic device (e.g., the electronic device 101 of FIG. 2) is in a folded state. In this case, when there is no extra space in the hinge portion for the heat dissipation sheet to be unfolded, the heat dissipation sheet may not be unfolded or damage due to interference may occur. When a heat dissipation sheet is attached to a printed circuit board, since the size of the heat dissipation sheet is limited to the size of the printed circuit board, heat transfer performance may be decreased. When a general heat dissipation sheet is used as an integral type, it may fracture due to a low elongation rate and, when a heat dissipation sheet with a high elongation rate is disposed, the heat transfer performance may be significantly lower compared to a general heat dissipation sheet due to low thermal conductivity.

According to the disclosure various embodiments may increase thermal conductivity of the foldable electronic device (e.g., the electronic device 101 of FIG. 2) and prevent/reduce fracture of the heat dissipation structure by disposing the heat dissipation layer 420 with high thermal conductivity on the flat area 403 of the foldable electronic device (e.g., the electronic device 101 of FIG. 2) and disposing the heat conductive layer 430 with a high elongation rate on the folding area 404.

According to the disclosure various embodiments may enable smooth heat dissipation between the first housing (e.g., the first housing 321 of FIG. 4) and the second housing (e.g., the second housing 322 of FIG. 4) in the foldable electronic device (e.g., the electronic device 101 of FIG. 2) by transferring heat generated in the first housing (e.g., the first housing 321 of FIG. 4) sequentially to the second housing (e.g., the second housing 322 of FIG. 4) through the first heat dissipation layer 421, the heat conductive layer 430, and the second heat dissipation layer 422.

The heat dissipation structure according to an embodiment of the disclosure has a simple shape and structure by stacking the heat conductive layer 430 on the heat dissipation layer 420, may maintain the original shape at the time of initial attachment, and even when the electronic device (e.g., the electronic device 101 of FIG. 2) is folded or unfolded, there are no considerations except that at least a portion of the heat dissipation structure is stretched, so design and fabrication may be easy.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. An electronic device comprising:
a first housing;
a second housing;
a hinge configured to rotatably couple the first housing and the second housing;
a flexible display configured to vary corresponding to a rotation of the second housing with respect to the first housing; and
a heat dissipation structure at least partially disposed between the flexible display and the hinge;
wherein the heat dissipation structure comprises:
a heat dissipation layer stacked with the flexible display, wherein the heat dissipation layer includes a first heat dissipation layer located in the first housing, and a second heat dissipation layer located in the second housing; and
a heat conductive layer stacked with at least a portion of the heat dissipation layer and configured to thermally couple the first heat dissipation layer and the second heat dissipation layer;
wherein the heat dissipation structure is configured to transfer heat from the first housing to the second housing through the first heat dissipation layer, the heat conductive layer, and the second heat dissipation layer.

2. The electronic device of claim 1, wherein the heat dissipation structure further comprises an anti-stick layer disposed between the heat conductive layer and the heat dissipation layer.

3. The electronic device of claim 1, wherein the heat dissipation structure includes:
a flat area including a first flat area disposed in the first housing and a second flat area disposed in the second housing, and
a folding area disposed between the first flat area and the second flat area,
wherein the first heat dissipation layer is disposed on the first flat area,
wherein the second heat dissipation layer is disposed on the second flat area, and
wherein at least a portion of the heat conductive layer is disposed on the folding area.

4. The electronic device of claim 1, wherein the first heat dissipation layer and the second heat dissipation layer are spaced apart from each other.

5. The electronic device of claim 1, wherein the heat dissipation layer is disposed between the heat conductive layer and the flexible display.

6. The electronic device of claim 1, wherein the heat conductive layer is disposed between the heat dissipation layer and the flexible display.

7. The electronic device of claim 1, wherein an elongation rate of the heat dissipation layer is lower than an elongation rate of the heat conductive layer, and
wherein a thermal conductivity of the heat dissipation layer is greater than a thermal conductivity of the heat conductive layer.

8. The electronic device of claim 1, wherein an elongation rate of the heat conductive layer is 10% or more.

9. The electronic device of claim 1, wherein a thermal conductivity of the heat conductive layer is 50 W/mK or less.

10. The electronic device of claim 1, wherein the heat dissipation structure further comprises, a surface protective layer including a first protective layer facing the flexible display and a second protective layer facing the hinge.

11. The electronic device of claim 10, wherein the heat dissipation structure further comprises, a first adhesive layer disposed between at least a portion of the heat dissipation layer and at least a portion of the first protective layer, and disposed side by side with the heat conductive layer.

12. The electronic device of claim 1, wherein the heat dissipation layer further comprises, a third heat dissipation layer stacked with at least a portion of the first heat dissipation layer and disposed side by side with the heat conductive layer, and a fourth heat dissipation layer stacked with at least a portion of the second heat dissipation layer and disposed side by side with the heat conductive layer.

13. The electronic device of claim 3, wherein:
the heat dissipation structure includes a folding area disposed between a first flat area disposed in the first housing and a second flat area disposed in the second housing, and
an anti-stick layer disposed between the heat conductive layer and the heat dissipation layer and disposed on the folding area.

14. The electronic device of claim 1, wherein
the heat dissipation structure is configured to transfer heat generated in the first housing from the first heat dissipation layer to the second heat dissipation layer.

15. The electronic device of claim 1, wherein
the heat dissipation structure is configured to sequentially transfer heat generated in the first housing to the second housing through the first heat dissipation layer, the heat conductive layer, and the second heat dissipation layer.

16. An electronic device comprising:
a first housing;
a second housing;
a hinge configured to rotatably couple the first housing and the second housing;
a flexible display configured to vary corresponding to a rotation of the second housing with respect to the first housing; and
a heat dissipation structure at least partially disposed between the flexible display and the hinge;
wherein the heat dissipation structure comprises:
a heat dissipation layer stacked with the flexible display, wherein the heat dissipation layer includes a first heat dissipation layer disposed in the first housing, and a second heat dissipation layer disposed in the second housing;
a heat conductive layer stacked with at least a portion of the heat dissipation layer and configured to thermally couple the first heat dissipation layer and the second heat dissipation layer;
an anti-stick layer disposed between the heat conductive layer and the heat dissipation layer; and
wherein the heat dissipation structure is configured to transfer heat from the first housing to the second housing through the first heat dissipation layer, the heat conductive layer, and the second heat dissipation layer.

17. The electronic device of claim 16,
wherein the heat dissipation structure comprises, a first flat area disposed on the first housing, a second flat area disposed on the second housing, and a folding area disposed between the first flat area and the second flat area, and
wherein the anti-stick layer is disposed on the folding area.

18. The electronic device of claim 17,
wherein the first heat dissipation layer is disposed at the first flat area and the second heat dissipation layer is disposed at the second flat area, and
wherein at least portion of the heat conductive layer is disposed at the folding area.

19. The electronic device of claim 16,
wherein the wherein an elongation rate of the heat dissipation layer is lower than an elongation rate of the heat conductive layer, and
wherein a thermal conductivity of the heat dissipation layer is greater than a thermal conductivity of the heat conductive layer.

20. The electronic device of claim 16,
wherein an elongation rate of the heat conductive layer is 10% or more, and
wherein a thermal conductivity of the heat conductive layer is 50 W/mK or less.
